(19) United States
(12) Patent Application Publication
(10) Pub. No.: US 2003/0132763 A1
(43) Pub. Date: Jul. 17, 2003

(54) Capacitance-based sensing device for detecting presence of body part

(76) Inventor: John David Ellenz, Olathe, KS (US)

Correspondence Address: THOMAS B. LUEBBERING, HOVEY WILLIAMS LLP, 2405 Grand, Suite 400, Kansas City, MO, 64108, US

(21) Appl. No.: 10/340,071

(22) Filed: Jan. 10, 2003

Related U.S. Application Data
(60) Provisional application No. 60/347,502, filed on Jan. 11, 2002.

(51) Int. Cl. G01R 27/26

(52) U.S. Cl. 324/663

(57) ABSTRACT

A capacitance-based sensing device (10) for detecting or determining a presence or proximity of a body or body part (12) in or near a garment, device, apparatus, or other item, such as, for example, an orthopedic device or exercise apparatus. Two or more conductive surfaces (16,18), interacting as a capacitor (17) having an actual capacitance, are embedded into the item, and the presence of the body part (12) is detected as a difference between the actual capacitance of the capacitor(17)formed by the conductive surfaces (16,18)and a reference capacitance.

### RELATED APPLICATIONS

The present application is related to and claims priority benefit of a co-pending provisional patent application titled “CAPACITIVE PROXIMITY SENSOR FOR DETECTING PRESENCE OF HUMAN BODY IN A GARMENT OR APPARATUS”, Serial No. 60/347,502, filed Jan. 11, 2002, the content of which is hereby incorporated into the present application by reference.

### BACKGROUND OF THE INVENTION

1. Field of the Invention

The present invention relates broadly to sensors or other sensing devices for detecting or determining a presence or proximity of a body part. More particularly, the present invention concerns a sensing device for detecting or determining a presence or proximity of a body or body part in or near a garment, device, apparatus, or other item, such as, for example, an orthopedic device or exercise apparatus, wherein the presence of the body part is detected as a change or difference in capacitance.

2. Description of the Prior Art

It is often desirable to detect or determine whether a human body or body part is present or nearby. This is particularly true, for example, when it is desired or required to determine whether a patient or other person is wearing an orthopedic device or using an exercise apparatus with a frequency and duration as directed. To that end, prior art devices exist that use a variety of techniques for accomplishing such detection. Prior art devices are known, for example, that are based on direct electrically conductive contact with the body part. Other prior art devices are known that are based on pressure exerted by the body part.

Unfortunately, these prior art devices suffer from a number of problems and disadvantages. Detection based on direct electrically conductive contact with the body part, for example, does not work or does not work as effectively when clothing, padding, or other fabric or material is interposed between the prior art device and the body part. Similarly, detection based on exerted pressure is not suitable for all situations, such as, for example, when the exerted pressure is unpredictable or insufficient. Furthermore, even where exerted pressure is predictably present and sufficient in force and duration, the positioning of the prior art device becomes crucial and may undesirably dictate the positioning or design of other nearby components or the item generally.

Due to the above-identified and other problems and disadvantages in the art, a need exists for an improved sensing mechanism for detecting a presence of a body part.

### SUMMARY OF THE INVENTION

The present invention overcomes the above-described and other problems and disadvantages in the prior art with a capacitance-based sensing device adapted to detect or determine a presence or proximity of a body or body part in a garment, orthopedic device, exercise apparatus, or other item.

In a preferred embodiment, the device broadly comprises a first conductor and a second conductor; a substrate; a shield; a capacitance measuring circuit; a controller; and a power source. The first and second conductors are electrically conductive plates constructed from a flexible copper sheet material and secured to a first side of the substrate. The first and second conductors interact as a capacitor having a measurable actual capacitance. The substrate is constructed of an electrically non-conductive flexible material, such as, for example, polyurethane.

The shield is constructed of an electrically conductive material and is operable to prevent the detection of body parts or other objects located in areas other than the area of interest. The shield is secured to a second side of the substrate so as to define and limit the area within which detection is desired. Because the first and second conductors, substrate, and shield are all constructed of flexible materials, these components of the device can be incorporated directly into the item without substantially affecting the wearer's or user's comfort.

The capacitance measuring circuit is operable to facilitate measuring the actual capacitance between the first and second conductors. The measuring circuit may be implemented in any of a variety of ways. In a preferred first implementation, for example, the actual capacitance between the first and second conductors is measured by charging the capacitor formed by the first and second conductors at a constant rate while measuring the time required for a particular voltage to be reached. In a preferred second or alternate implementation, the actual capacitance between the first and second conductors is measured by using the capacitor formed by the first and second conductors as a “bucket” capacitor in a charge transfer arrangement. The frequency with which the measuring circuit makes its measurements is substantially application dependent. When monitoring a patient's compliance in using an orthopedic device, for example, it may be sufficient to make between one and ten measurements per minute. Also, the measuring circuit may, as desired, be powered down between measurements to conserve power.

The controller is operable to control the measuring circuit and, based on the measured actual capacitance, to determine and communicate the presence or absence of the body part. In more detail, the controller determines or receives the actual capacitance from the measuring circuit; compares the actual capacitance to a known or reference capacitance measurement corresponding to the body part being present; and, based on the comparison, determines whether the body part is present or not. Processing by the controller may also include a high-pass filter so that only sudden changes in actual capacitance will be considered, which advantageously minimizes false presence determinations due to slow, long-term changes in actual capacitance arising from deformation or moisture absorption of surrounding material.

The power supply is preferably a battery but may be any suitable power source operable to provide power to the measuring circuit and the controller.

In exemplary use and operation, the body part positioned near the first and second conductors acts as a highly capacitive device because of an abundance of electrolytic fluid (saline or salt solution) within the body part. The surfaces of the body part and the first conductor form a first capacitor whose first capacitance is directly proportional to the parallel surface area of the body part to the first conductor and the distance between the body part and the first conductor. Thus, as the body part moves closer to the first conductor, the first capacitance rises. Similarly, the surfaces of the body part and the second conductor interact to form a second capacitor having a second capacitance.

It will be appreciated that the total capacitance between the first conductor and the second conductor can be modeled as the first capacitance and the second capacitance connected in series. The presence of the body part is determined by measuring with the measuring circuit the actual capacitance between the first conductor and the second conductor, and then comparing the result with the reference capacitance corresponding to the body part being present. If the measured capacitance is greater than this reference capacitance, then it is determined that the body part is present.

Thus, it will be appreciated that the device of the present invention provides a number of substantial advantages over the prior art, including, for example, using capacitance, rather than direct electrically conductive contact or exerted pressure, to determine the presence of the body part, thereby accommodating a greater variety of applications. Furthermore, the physical flexibility of the first and second conductors, the substrate, and the shield advantageously allows for incorporating these components of the device directly into the item without substantially affecting the wearer's or user's comfort. Additionally, the shield advantageously allows for substantially eliminating false readings by shielding the first and second conductors from objects outside the area of interest. Additionally, the measuring circuit can be powered-down between measurements, thereby advantageously conserving power. Additionally, the controller can be made to apply a high-pass to advantageously distinguish between a rapid increase in actual capacitance due to the presence of the body part and a slow increase in actual capacitance over time due to moisture absorption or deformation.

These and other important features of the present invention are more fully described in the section titled DETAILED DESCRIPTION OF A PREFERRED EMBODIMENT, below.

### BRIEF DESCRIPTION OF THE DRAWINGS

A preferred embodiment of the present invention is described in detail below with reference to the attached drawing figures, wherein:

FIG. 1 is a block diagram of a preferred embodiment of a capacitance-based sensing device of the present invention;

FIG. 2 is a circuit diagram of a preferred first implementation of a capacitance measuring circuit component of the sensing device of FIG. 1;

FIG. 3 is a circuit diagram of a preferred second implementation of the capacitance measuring circuit component of the sensing device of FIG. 1; and

FIG. 4 is a sectional view of portions of the sensing device of FIG. 1 during exemplary operation.

### DETAILED DESCRIPTION OF A PREFERRED EMBODIMENT

Referring to the figures, a capacitance-based sensing device 10 is shown constructed in accordance with a preferred embodiment of the present invention. The device 10 is adapted to detect or determine a presence or proximity of a human body or body part 12 based upon a change or difference in capacitance. By way of example and not limitation, it will be appreciated that a potential application for the device 10 is to monitor use of a garment, orthopedic device, exercise apparatus, or other item.

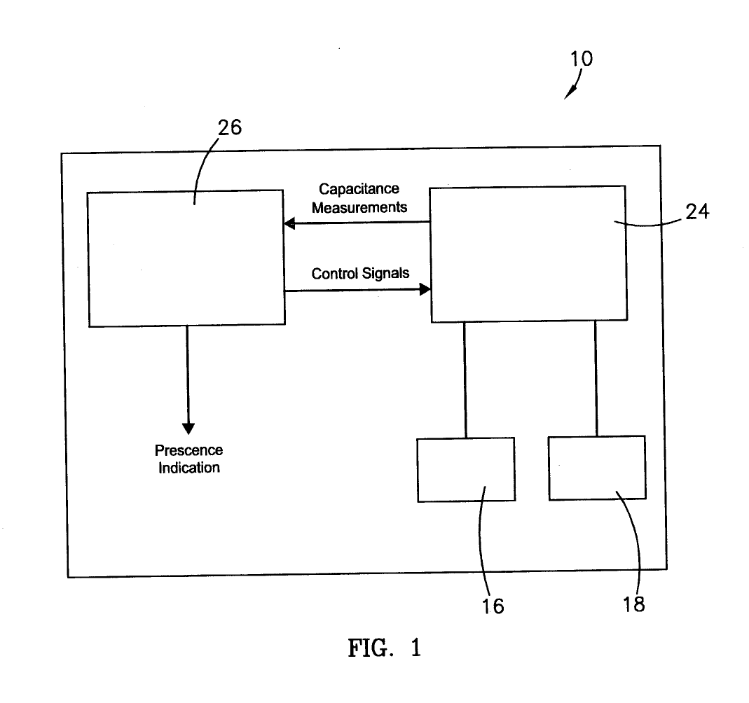

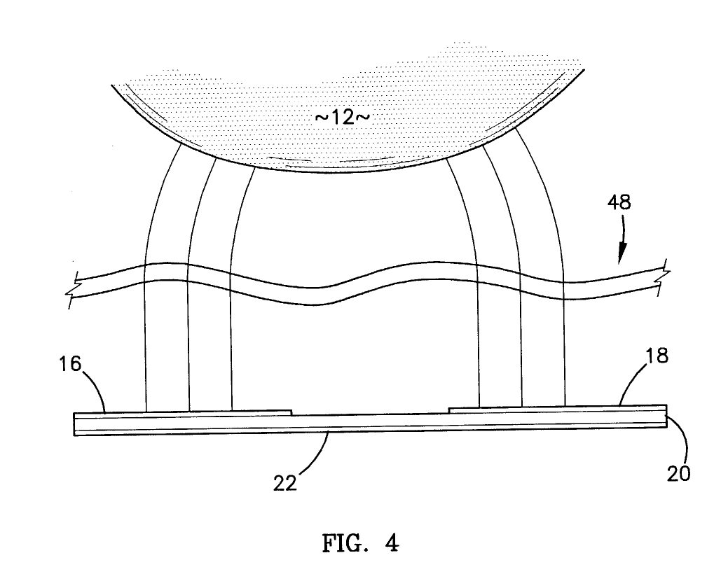

In the preferred embodiment, referring particularly to FIGS. 1 and 4, the device 10 broadly comprises a first conductor 16 and a second conductor 18; a substrate 20; a shield 22; a capacitance measuring circuit 24; a controller 26; and a power source 28. The first and second conductors 16,18 may be substantially any electrical conductor of any shape and material, but are preferably electrically conductive plates constructed from flexible copper sheet material in the form of a flexible printed circuit. The first and second conductors 16,18 interact as a capacitor 17 having a measurable actual capacitance. The first and second conductors 16,18 are secured to a first side of the substrate 20. The substrate 20 is preferably constructed of an electrically non-conductive flexible material, such as, for example, polyurethane.

The shield 22 is constructed of electrically conductive material and is operable to prevent the detection of body parts or other objects located in areas other than the area of interest. Thus, the shield 22 is strategically located so as to define and limit the area within which detection is desired. Preferably, the shield 22 is constructed from the same flexible copper sheet material as the first and second conductors 16,18, and secured to a second side of the substrate 20. The shield 22 itself forms a capacitor with the first and second conductors 16,18. This effect is accounted for, however, by measuring the capacitance associated with the shield 22 when the body part 12 is known to not be present, and then subtracting the capacitance associated with the shield 22 from any future readings. Because the first and second conductors 16,18, substrate 20, and shield 22 are all constructed of flexible materials, these components of the device 10 can be incorporated directly into the garment, device, or apparatus without substantially affecting the wearer's or user's comfort.

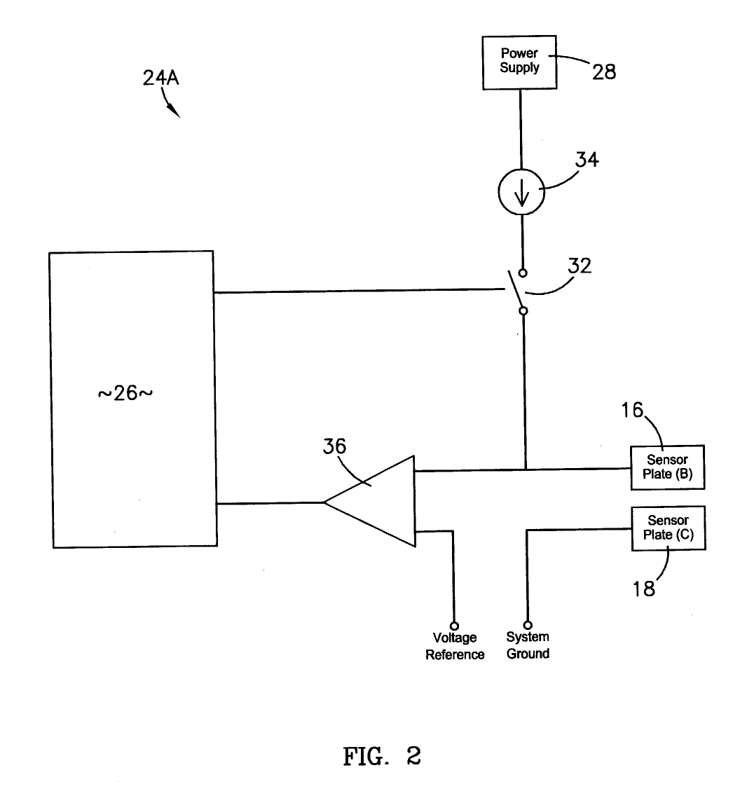

The capacitance measuring circuit 24 is substantially conventionally operable to facilitate measuring the actual capacitance of the capacitor 17 formed by first and second conductors 16,18. It will be appreciated that the measuring circuit 24 may be implemented in any of a variety of ways. By way of example and not limitation, two preferred implementations are set forth below. Referring particularly to FIG. 2, a preferred first implementation of the measuring circuit 24A is shown including a CMOS switch 32; a constant current source 34; and a voltage comparator 36. Broadly, the actual capacitance of the capacitor 17 is measured by charging the capacitor 17 at a constant rate while measuring the time required for a particular voltage to be reached.

In more detail, the controller 26 controls operation of the CMOS switch 32 and initiates the measurement by causing the CMOS switch 32 to connect the constant current power source 34 with the capacitor 17 in order to charge it. The constant current source 34 provides current to the capacitor 17 at a rate that is independent of the instantaneous voltage on the capacitor 17. All the while, the controller 26 measures, either using a counter or by counting instruction clock cycles, the time required, after closing the CMOS switch 32, until the capacitor 17 reaches a voltage equal to a voltage reference. The voltage comparator 36 provides a signal to the controller 26 when this event occurs.

Knowing the voltage and the time required to achieve it, the controller 26 calculates the actual capacitance as follows. The voltage on the capacitor 17 is directly proportional to the charge on the capacitor 17 and the capacitance value of the capacitor 17: voltage=total charge/capacitance. The total charge is equal to the rate of charge multiplied by the duration of charge: voltage=(time)(current flow)/capacitance. Because the current flow is constant, and the voltage and the time are accurately known or measured, the actual capacitance of the capacitor 17 formed by the first and second conductors 16,18 can be determined: capacitance=(time)(current flow)/voltage.

When using this method of determining actual capacitance, the capacitor 17 must first be completely discharged. This can be accomplished with a transistor (not shown) or second CMOS switch (not shown).

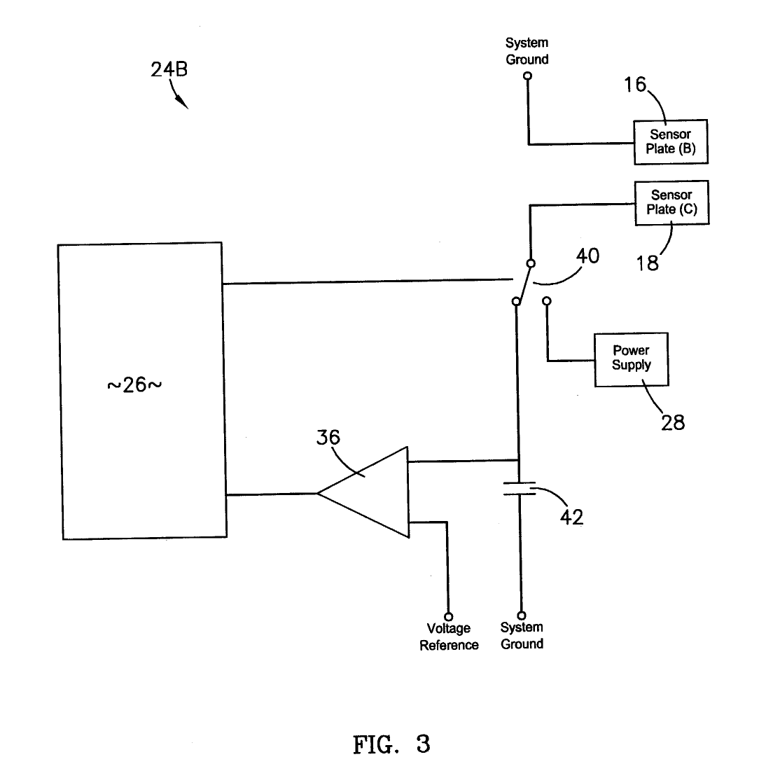

Referring particularly to FIG. 3, a preferred second or alternate implementation for the measuring circuit 24B is shown including a CMOS switch 40; a large tank capacitor 42; and a voltage comparator 44. The power supply 28 in this case is a low-impedance voltage source. Broadly, the actual capacitance of the capacitor 17 formed by the first and second conductors 16,18 is measured by using the capacitor 17 as a “bucket” capacitor in a charge transfer arrangement.

In more detail, the controller 26 controls operation of the CMOS switch 40, and initiates the measurement by causing the CMOS switch 40 to connect the low-impedance voltage source 28 with the capacitor 17 in order to charge it. The capacitor 17 should always be completely charged to the voltage level of the low-impedance voltage source 28. The amount of charge held on the capacitor 17 is based solely on its capacitance value, without regard to any time constant. After the capacitor 17 is charged, the CMOS switch 40 is made to connect the tank capacitor 42 with the low-impedance voltage source 28 to charge the tank capacitor 42. Thereafter, the controller 26 causes the CMOS switch 40 to begin switching the capacitor 17 between the tank capacitor 42 and the low-impedance voltage source 28. With each switching cycle, an amount of charge is transferred. The controller 26 counts the number of switching cycles required for the voltage on the tank capacitor 42 to reach the voltage reference and trigger the voltage comparator 44, and, based thereon, determines the actual capacitance of the capacitor 17.

When using this second implementation, the tank capacitor 42 must be completely discharged prior to beginning the measurement. This can be accomplished using either a transistor (not shown) or a second CMOS transistor (not shown).

The frequency with which the measuring circuit 20 makes its measurements is substantially application dependent. In one exemplary application, monitoring compliance with using an orthopedic device, it may be sufficient to make between one and ten measurements per minute. Additionally, the measuring circuit 24 may, as desired, be powered down between measurements to conserve power.

The controller 26 is substantially conventionally operable to control the measuring circuit 28, as described above, and, based on the measured actual capacitance, to determine and communicate the presence of the body part 12. In more detail, the controller 26 determines or receives the actual capacitance measurements from the measuring circuit 24; compares the actual capacitance measurements to a known or reference capacitance measurement when the body part 12 is not present; and, based on the comparison, determines whether the body part 12 is present or not. The controller 26 may be implemented in software, firmware, hardware, or any combination thereof, and may use any substantially conventional control device, such as, for example, a microcontroller or microprocessor.

Processing by the controller 22 may also include a high-pass filter so that only sudden changes in actual capacitance will be considered when determining the presence of the body part 12. This substantially reduces or eliminates false presence determinations due to slow, long-term changes in actual capacitance arising from deformation or moisture absorption of surrounding material.

The power supply 28 is preferably a battery but may be any suitable power source operable to provide power to the measuring circuit 24 and the controller 26. As mentioned, in the preferred second implementation of the measuring circuit 24B the power supply 28 is a low-impedance voltage source.

In exemplary use and operation, referring particularly to FIG. 4, the device 10 is attached, embedded, or otherwise incorporated into the garment, orthopedic device, exercise apparatus, or other item. An electrically non-conductive fabric (e.g., clothing), padding, or other material 48 may be interposed between the body part 12 and the device 10. This material 48 will form its own capacitor with the first and second conductors 16,18, much like the shield 22 does. This effect is similarly accounted for, however, by measuring the capacitance associated with the material 48 when the body part 12 is known to not be present, and then subtracting the capacitance associated with the material 48 from any future readings.

The body part 12 positioned near the first and second conductors 16,18 acts as a highly capacitive device because of an abundance of electrolytic fluid (saline or salt solution) within the body part 12. The surfaces of the body part 12 and the first conductor 16 form a first capacitor whose first capacitance is directly proportional to the parallel surface area of the body part 12 to the first conductor 16 and the distance between the body part 12 and the first conductor 16. Thus, as the body part 12 moves closer to the first conductor 16, the first capacitance rises.

Similarly, the surfaces of the body part 12 and the second conductor 18 form a second capacitor whose second capacitance is directly proportional to the parallel surface area of the body part 12 to the second conductor 18 and the distance between the body part 12 and the second conductor 18. Thus, as the body part 12 moves closer to the second conductor 18, the second capacitance rises. The total actual capacitance between the first conductor 16 and the second conductor 18 can be modeled as the first capacitance and the second capacitance in series, so that:

Cₜₒₜₐₗ=(C_{body|first conductor}*C_{body|second conductor})/(C_{body|first conductor}+C_{body|second conductor})

Thus, the presence of the body part 12 can be determined by measuring with the measuring circuit 24 the actual capacitance between the first conductor 16 and the second conductor 18, and then comparing the result with the reference capacitance known to exist when the body part 12 is not present. If the measured actual capacitance is greater than this reference capacitance, then it is determined that the body part 12 is present.

From the preceding description, it will be appreciated that the device 10 of the present invention provides a number of substantial advantages over the prior art, including, for example, using capacitance, rather than direct electrically conductive contact or exerted pressure, to determine the presence of the body part 12, and thereby accommodating a greater variety of applications. Furthermore, the physical flexibility of the first and second conductors 16,18, the substrate 20, and the shield 22 advantageously allows for incorporating these components of the device 10 directly into the item without substantially affecting the wearer's or user's comfort. Additionally, the shield 22 advantageously allows for substantially eliminating false readings by shielding the first and second conductors 16,18 from objects outside the area of interest. Additionally, the measuring circuit 24 can be powered-down between measurements, thereby advantageously conserving power. Additionally, the controller 26 can be made to apply a high-pass to advantageously distinguish between a rapid increase in actual capacitance due to the presence of the body part 12 and a slow increase in actual capacitance over time due to moisture absorption or deformation.

Although the invention has been described with reference to the preferred embodiments illustrated in the attached drawings, it is noted that equivalents may be employed and substitutions made herein without departing from the scope of the invention as recited in the claims. It will be appreciated, for example, that a variety of different capacitance measuring circuits are possible, and that the device is not limited to the two preferred implementations disclosed herein.

Having thus described the preferred embodiment of the invention, what is claimed as new and desired to be protected by Letters Patent includes the following:

1. A device for detecting a presence of a body part, the device comprising:
a capacitor incorporated into an item;
a capacitance measuring circuit adapted to facilitate measuring an actual capacitance of the capacitor; and
a controller adapted to compare the actual capacitance with a reference capacitance, wherein the presence of the body part is determined as a difference between the actual capacitance and the reference capacitance.

2. The device as set forth in claim 1, wherein the item is a garment.

3. The device as set forth in claim 1, wherein the item is an orthopedic device.

4. The device as set forth in claim 1, wherein the item is an exercise apparatus.

5. The device as set forth in claim 1, wherein the capacitor is formed by a first conductor and a second conductor.

6. The device as set forth in claim 5, wherein the first conductor and the second conductor are each comprised of a flexible electrically conducting sheet material.

7. The device as set forth in claim 6, further including a substrate comprised of a flexible electrically non-conducting material and having a first side and a second side, with the first conductor and the second conductor being secured to the first side.

8. The device as set forth in claim 7, further including a shield adapted to prevent detection of the body part outside of a detection area, wherein the shield is also comprised of the flexible electrically conducting sheet material and is secured to the second side of the substrate.

9. The device as set forth in claim 1, wherein the capacitance measuring circuit includes—
a switch controlled by the controller;
a constant current source for charging the capacitor when the switch is closed by the controller; and
a voltage comparator for comparing an actual voltage on the capacitor with a reference voltage,
wherein the controller is operable to measure an elapsed time required after closing the switch until the voltage comparator indicates that the actual voltage equals the reference voltage, and further operable to determine the actual capacitance based upon the actual voltage and the elapsed time.

10. The device as set forth in claim 1, wherein the capacitance measuring circuit includes—
a switch controlled by the controller;
a low impedance voltage source for charging the capacitor when the switch is closed by the controller;
a tank capacitor for transferring a charge with the capacitor; and
a voltage comparator for comparing an actual voltage on the tank capacitor with a reference voltage,
wherein, the controller is operable to, after the capacitor is charged, cause the switch to complete a number of switches between the capacitor and the tank capacitor so that, with each switch, an amount of charge is transferred therebetween, the controller being further operable to count the number of switches required until the voltage comparator indicates that the actual voltage on the tank capacitor equals the reference voltage, and then determine the actual capacitance based upon the number of switches and the actual voltage on the tank capacitor.

11. The device as set forth in claim 1, wherein the controller uses a high pass filter to substantially eliminate a slow increase in the actual capacitance that is not attributable to the presence of the body part.

12. A sensing device for detecting a presence of a body part, the sensing device comprising:
a first conductor and a second conductor interacting as a capacitor, with the first conductor and the second conductor each being comprised of a flexible electrically conducting sheet material;
a shield adapted to partially shield the first and second conductors to prevent detection of the body part outside of a detection area, wherein the shield is also comprised of the flexible electrically conducting sheet material;
a capacitance measuring circuit adapted to facilitate measuring an actual capacitance of the capacitor formed by the first conductor and the second conductor; and
a controller adapted to compare the actual capacitance with a reference capacitance, wherein the presence of the body part is determined as a difference between the actual capacitance and the reference capacitance.

13. The sensing device as set forth in claim 12, wherein the sensing device is incorporated into a garment.

14. The sensing device as set forth in claim 12, wherein the sensing device is incorporated into an orthopedic device.

15. The sensing device as set forth in claim 12, wherein the sensing device is incorporated into an exercise apparatus.

16. The sensing device as set forth in claim 12, wherein the capacitance measuring circuit includes—
a switch controlled by the controller;
a constant current source for charging the capacitor formed by the first and second conductors when the switch is closed by the controller; and
a voltage comparator for comparing an actual voltage on the capacitor with a reference voltage,
wherein the controller is operable to measure an elapsed time required after closing the switch until the voltage comparator indicates that the actual voltage equals the reference voltage, and further operable to determine the actual capacitance based upon the actual voltage and the elapsed time.

17. The sensing device as set forth in claim 12, wherein the capacitance measuring circuit includes—
a switch controlled by the controller;
a low impedance voltage source for charging the capacitor formed by the first and second conductors when the switch is closed by the controller;
a tank capacitor for transferring a charge with the capacitor formed by the first and second conductors; and
a voltage comparator for comparing an actual voltage on the tank capacitor with a reference voltage,
wherein, the controller is operable to, after the capacitor formed by the first and second conductors is charged, cause the switch to complete a number of switches between the capacitor formed by the first and second conductors and the tank capacitor so that, with each switch, an amount of charge is transferred therebetween, the controller being further operable to count the number of switches required until the voltage comparator indicates that the actual voltage on the tank capacitor equals the reference voltage, and then determine the actual capacitance based upon the number of switches and the actual voltage on the tank capacitor.

18. The sensing device as set forth in claim 12, wherein the controller uses a high pass filter to substantially eliminate a slow increase in the actual capacitance that is not attributable to the presence of the body part.

19. The sensing device as set forth in claim 12, further including a substrate comprised of a flexible electrically non-conducting material and having a first side and a second side, with the first conductor and the second conductor being secured to the first side.

20. A sensing device for detecting a presence of a body part, with the sensing device being incorporated into an item, the sensing device comprising:
a first conductor and a second conductor interacting as a capacitor, with the first conductor and the second conductor each being comprised of a flexible electrically conducting sheet material;
a shield adapted to partially shield the first and second conductors to prevent detection of the body part outside of a detection area, wherein the shield is also comprised of the flexible electrically conducting sheet material;
a substrate comprised of a flexible electrically non-conducting material and having a first side and a second side, with the first conductor and the second conductor being secured to the first side and the shield being secured to the second side;
a capacitance measuring circuit adapted to facilitate measuring an actual capacitance of the capacitor formed by the first conductor and the second conductor; and
a controller adapted to compare the actual capacitance with a reference capacitance, wherein the presence of the body part is determined as a difference between the actual capacitance and the reference capacitance, with the controller using a high pass filter to substantially eliminate a slow increase in the actual capacitance that is not attributable to the presence of the body part.

21. The sensing device as set forth in claim 20, wherein the item is a garment.

22. The sensing device as set forth in claim 20, wherein the item is an orthopedic device.

23. The sensing device as set forth in claim 20, wherein the item is an exercise apparatus.

24. The sensing device as set forth in claim 20, wherein the capacitance measuring circuit includes—
a switch controlled by the controller;
a constant current source for charging the capacitor formed by the first and second conductors when the switch is closed by the controller; and
a voltage comparator for comparing an actual voltage on the capacitor with a reference voltage,
wherein the controller is operable to measure an elapsed time required after closing the switch until the voltage comparator indicates that the actual voltage equals the reference voltage, and further operable to determine the actual capacitance based upon the actual voltage and the elapsed time.

25. The sensing device as set forth in claim 20, wherein the capacitance measuring circuit includes—
a switch controlled by the controller;
a low impedance voltage source for charging the capacitor formed by the first and second conductors when the switch is closed by the controller;
a tank capacitor for transferring a charge with the capacitor formed by the first and second conductors; and
a voltage comparator for comparing an actual voltage on the tank capacitor with a reference voltage,
wherein, the controller is operable to, after the capacitor formed by the first and second conductors is charged, cause the switch to complete a number of switches between the capacitor formed by the first and second conductors and the tank capacitor so that, with each switch, an amount of charge is transferred therebetween, the controller being further operable to count the number of switches required until the voltage comparator indicates that the actual voltage on the tank capacitor equals the reference voltage, and then determine the actual capacitance based upon the number of switches and the actual voltage on the tank capacitor.
